(19) United States
(12) Patent Application Publication
(10) Pub. No.: US 2025/0192524 A1
(43) Pub. Date: Jun. 12, 2025

(54) METER SOCKET FOR ELECTRIC METER WITH DISTRIBUTED ENERGY RESOURCE PORT

(71) Applicant: MILBANK MANUFACTURING CO., KANSAS CITY, MO (US)

(72) Inventors: SHAWN GLASGOW, KANSAS CITY, MO (US); JOHN RYAN KUHL, KANSAS CITY, MO (US)

(21) Appl. No.: 18/969,349

(22) Filed: Dec. 5, 2024

Related U.S. Application Data
(60) Provisional application No. 63/686,927, filed on Aug. 26, 2024.
(60) Provisional application No. 63/609,029, filed on Dec. 12, 2023.

(51) Int. Cl. H02B 1/03; G01R 22/06

(52) U.S. Cl. CPC H02B 1/03; G01R 22/065

(57) ABSTRACT

A DER port jaw assembly for use with a meter socket having a base, a bus bar mounted to the base, a DER port meter jaw mounted to the base and electrically coupled to the bus bar, and a DER electrical connector mounted to the base and electrically coupled to the bus bar. A meter jaw block assembly including an insulating block and the DER port jaw assembly. A meter socket including a meter socket enclosure, an insulating block, and the DER port jaw assembly.

### CROSS-REFERENCE TO RELATED APPLICATIONS

This application is based on and claims priority to U.S. Provisional Application Ser. No. 63/686,927 filed on Aug. 26, 2024, and U.S. Provisional Application Ser. No. 63/609,029 filed on Dec. 12, 2023, both of which are hereby incorporated herein by reference.

### BACKGROUND OF THE INVENTION

An electric meter is typically used to measure the power consumption of a structure. The electric meter is typically installed in a meter socket that connects to line side conductors from the utility and load side conductors for the structure. Distributed energy resource (“DER”) devices, for example, solar panels, wind turbines, or electric batteries, may be in use at the structure to provide power to the structure separate from the utility power, or receive utility provided power. If the utility desires to measure the power generation or consumption of the DER device, it may be necessary to install a second meter at the structure for the DER device.

### BRIEF SUMMARY OF THE INVENTION

A DER port jaw assembly for use with a meter socket having a base, a bus bar mounted to the base, a DER port meter jaw mounted to the base and electrically coupled to the bus bar, and a DER electrical connector mounted to the base and electrically coupled to the bus bar. The DER port jaw assembly may be used with a meter socket so that a meter can electrically connect to the DER port meter jaws and line and load meter jaws. Connected in this manner, the meter may provide power to, or receive power from, the DER port meter jaws and a DER device connected to the DER electrical connectors (e.g., a solar panel, wind turbine, or electric vehicle batteries). A meter jaw block assembly in accordance with an additional aspect of the invention described herein includes an insulating block and the DER port jaw assembly. A meter socket in accordance with yet another aspect of the invention described herein includes a meter socket enclosure, an insulating block, and the DER port jaw assembly.

Additional aspects of the invention, together with the advantages and novel features appurtenant thereto, will be set forth in part in the description which follows, and in part will become apparent to those skilled in the art upon examination of the following, or may be learned from the practice of the invention. The objects and advantages of the invention may be realized and attained by means of the instrumentalities and combinations particularly pointed out in the appended claims.

### BRIEF DESCRIPTION OF THE DRAWINGS

Various exemplary embodiments of the present invention are described in detail below with reference to the attached drawing figures, wherein:

FIG. 1 is a perspective view of a meter socket in accordance with an exemplary embodiment of the invention described herein;

FIG. 2 is a perspective view of a meter jaw block assembly of the meter socket;

FIG. 3 is a rear perspective view of the meter jaw block assembly;

FIG. 4 is a perspective view of the meter jaw block assembly with a safety shield removed;

FIG. 5 is a front elevational view of the meter jaw block assembly;

FIG. 6 is a front perspective view of an insulating block of the meter jaw block assembly;

FIG. 7 is a perspective view of two meter jaws and two electrical connectors of the meter jaw block assembly;

FIG. 8 is a perspective view of an electrical connector of the meter jaw block assembly;

FIG. 9 is a partially exploded view of the meter jaw block assembly;

FIG. 10 is a perspective view of a DER port jaw assembly of the meter jaw block assembly;

FIG. 11 is a rear perspective view of the DER port jaw assembly;

FIG. 12 is a perspective view of a base of the DER port jaw assembly;

FIG. 13 is a perspective view of a bus bar and a meter jaw of the DER port jaw assembly;

FIG. 14 is a top plan view of the bus bar and the meter jaw shown in FIG. 13;

FIG. 15 is an exploded view of the bus bar and the meter jaw shown in FIG. 13;

FIG. 16 is a perspective view of the DER port jaw assembly showing an electrical connector;

FIG. 17 is a cross-sectional view of the DER port jaw assembly;

FIG. 18 is a perspective view of an additional embodiment of a meter jaw block assembly for use with a meter socket;

FIG. 19 is a perspective view of an alternative embodiment of DER port jaw assembly that may be used with the meter jaw block assembly shown in FIGS. 2-9;

FIG. 20 is a rear perspective view of the DER port jaw assembly shown in FIG. 19;

FIG. 21 is a perspective view of a base of the DER port jaw assembly shown in FIG. 19;

FIG. 22 is a perspective view of a bus bar and meter jaw of the DER port jaw assembly shown in FIG. 19;

FIG. 23 is a cross-sectional view of the DER port jaw assembly shown in FIG. 19;

FIG. 24 is a perspective view of an alternative embodiment of meter jaw block assembly that may be used with the meter socket enclosure shown in FIG. 1;

FIG. 25 is a front elevational view of the meter jaw block assembly shown in FIG. 24;

FIG. 26 is a rear perspective view of the meter jaw block assembly shown in FIG. 24;

FIG. 27 is a perspective view of an insulating block, meter jaws, and electrical connectors of the meter jaw block assembly shown in FIG. 24;

FIG. 28 is a partially exploded view of the insulating block, meter jaws, and electrical connectors shown in FIG. 27;

FIG. 29 is a partially exploded view of the meter jaw block assembly shown in FIG. 24;

FIG. 30 is a perspective view of a DER port jaw assembly of the meter jaw block assembly shown in FIG. 24;

FIG. 31 is a rear perspective view of the DER port jaw assembly shown in FIG. 30;

FIG. 32 is a perspective view of a base of the DER port jaw assembly shown in FIG. 30;

FIG. 33 is a perspective view of a meter jaw and electrical connector of the DER port jaw assembly shown in FIG. 30; and

FIG. 34 is a rear perspective view of the meter jaw and electrical connector shown in FIG. 33.

### DETAILED DESCRIPTION OF EXEMPLARY EMBODIMENTS

The invention described herein is directed to a distributed energy resource (“DER”) port jaw assembly for use with a meter socket, and the combination of the DER port jaw assembly with both a meter jaw block assembly of the meter socket and the entire meter socket. The DER port jaw assembly may be used with a meter socket so that a meter can electrically connect to DER port meter jaws and line and load meter jaws. Connected in this manner, the meter may provide power to, or receive power from, the DER port meter jaws and a DER device connected to the DER electrical connectors (e.g., a solar panel, wind turbine, or electric vehicle batteries). While the invention will be described in detail below with reference to various exemplary embodiments, it should be understood that the invention is not limited to the specific configurations of these embodiments. In addition, although the exemplary embodiments are described as embodying several different inventive features, one skilled in the art will appreciate that any one of these features could be implemented without the others in accordance with the invention.

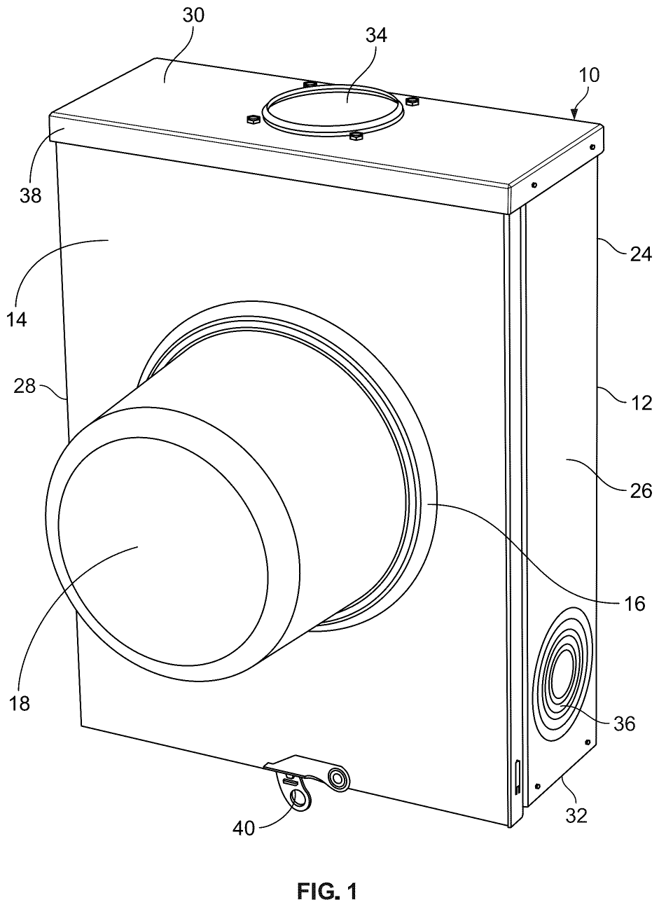

FIG. 1 shows a single-phase power system comprising an electric watt-hour meter 18 installed within a meter socket 10 in accordance with a first exemplary embodiment of DER port jaw assembly and meter socket. Meter socket 10 is known as a “ringless” meter socket and has a standardized form to allow the interchangeability of meters from various manufacturers without removing any wires or cables. While meter socket 10 may be employed for meters capable of continuous full load currents of 20 to 400 amperes, it is most typically utilized for residential applications of 200 amperes.

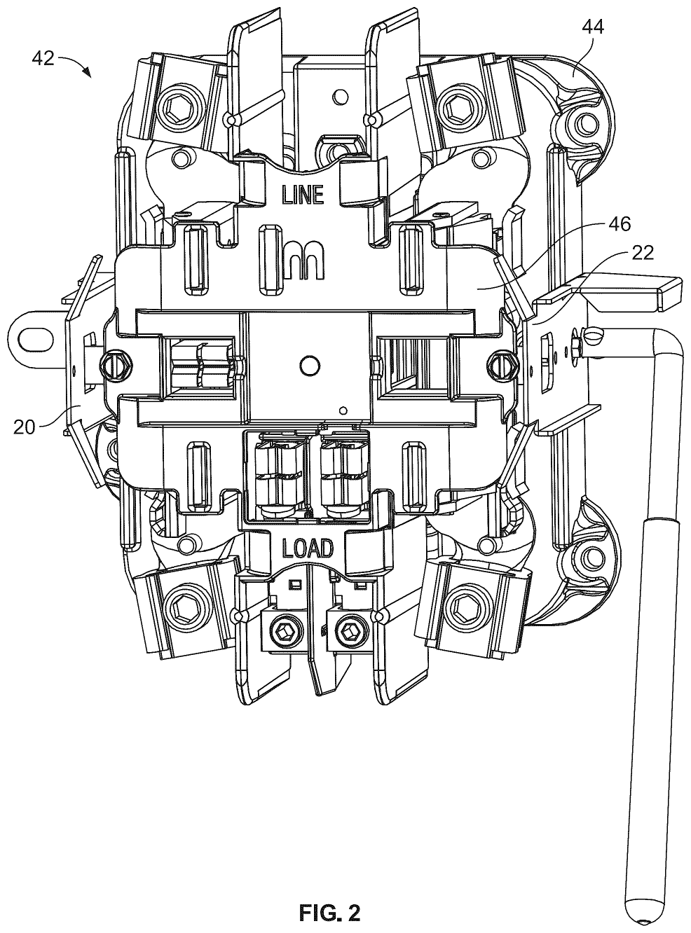

Meter socket 10 includes an enclosure 12 having a front wall or cover 14 with a raised embossment 16 surrounding a circular opening through which a meter 18 extends. Raised embossment 16 engages the meter 18 when cover 14 is latched to thereby retain meter 18 against meter supports 20 and 22 (shown in FIG. 2). Thus, it can be appreciated that meter 18 can only be removed from meter socket 10 if cover 14 is removed from meter socket enclosure 12.

Meter socket enclosure 12 also includes a back wall 24, a pair of laterally spaced side walls 26 and 28, a top wall 30, and a bottom wall 32. Side walls 26 and 28 are integral with back wall 24 and are formed by bending side portions of an enclosure blank. Top and bottom walls 30 and 32 are formed as separate members and are secured to back wall 24 and side walls 26 and 28 by any suitable attachment means, such as by spot welding, fasteners, or the like. Of course, top and bottom walls 30 and 32 could alternatively be formed integral with back wall 24.

Top wall 30 is provided with an opening 34 to receive the power supply conductors (not shown) from the electric power utility. Bottom wall 32 and lower portions of side walls 26 and 28 and back wall 24 are provided with knock-outs, one of which is identified as 36, which may be selectively opened to enable the power load conductors (not shown) to exit enclosure 12 for routing to a customer premises. Back wall 24 is provided with preformed holes that receive fasteners to secure enclosure 12 to a supporting wall.

To accommodate cover 14, side walls 26 and 28 include inset edges while top and bottom walls 30 and 32 include top and bottom flanges (top flange is identified as 38). The upper edge of cover 14 fits under top flange 38 and the inturned side edges of cover 14 overlap inset edges of the side walls 26 and 28. The bottom flange of the bottom wall 32 underlies the bottom edge of cover 14. The bottom flange is provided with a slotted tab that engages a latch 40 rotationally fixed by a rivet to cover 14. Electric power utility personnel use a custom tool to secure the latch 40 and prevent unauthorized removal of cover 14 (and thus meter 18) from meter socket 10. While enclosure 12 is described in detail above, other types of meter socket enclosures may be used with the invention described herein.

FIG. 2 shows an exemplary meter jaw block assembly 42 of the meter socket 10. The meter jaw block assembly 42 is mounted within the enclosure 12 shown in FIG. 1. The meter jaw block assembly 42 may be mounted to the back wall 24 or another structure, like a riser, mounted to the back wall 24. The meter jaw block assembly 42 includes an insulating block 44 that mounts to the enclosure 12. Meter supports 20 and 22 are mounted to the insulating block 44, and a safety shield 46 is mounted to the meter supports 20 and 22. The meter supports 20 and 22 may provide a mounting surface and transient suppression ground terminal for meter 18.

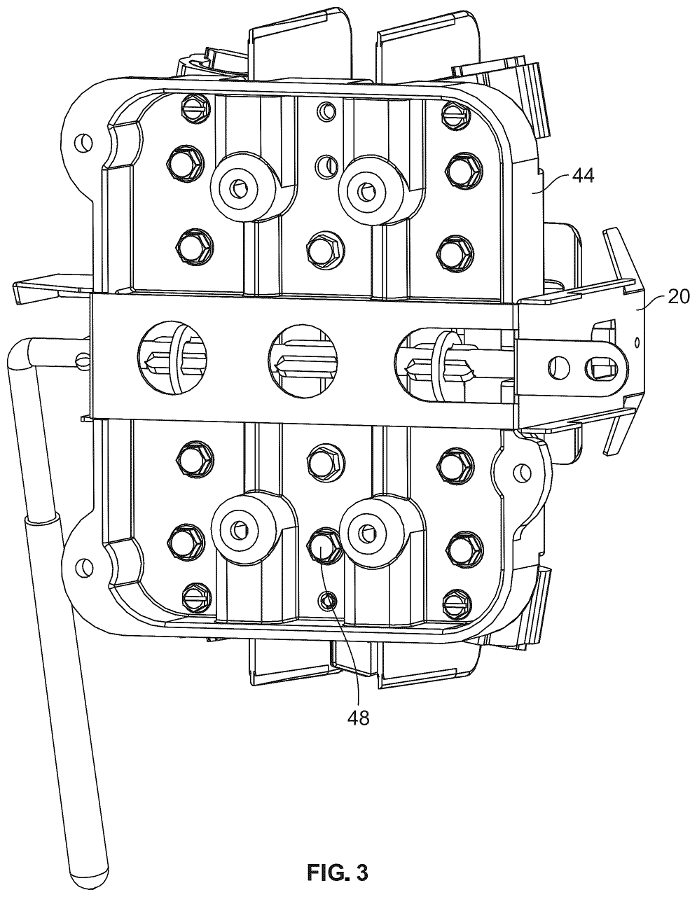

FIG. 3 shows a rear of the insulating block 44 and a plurality of fasteners (e.g., screws), one of which is identified as 48, for mounting the components described below to the insulating block 44.

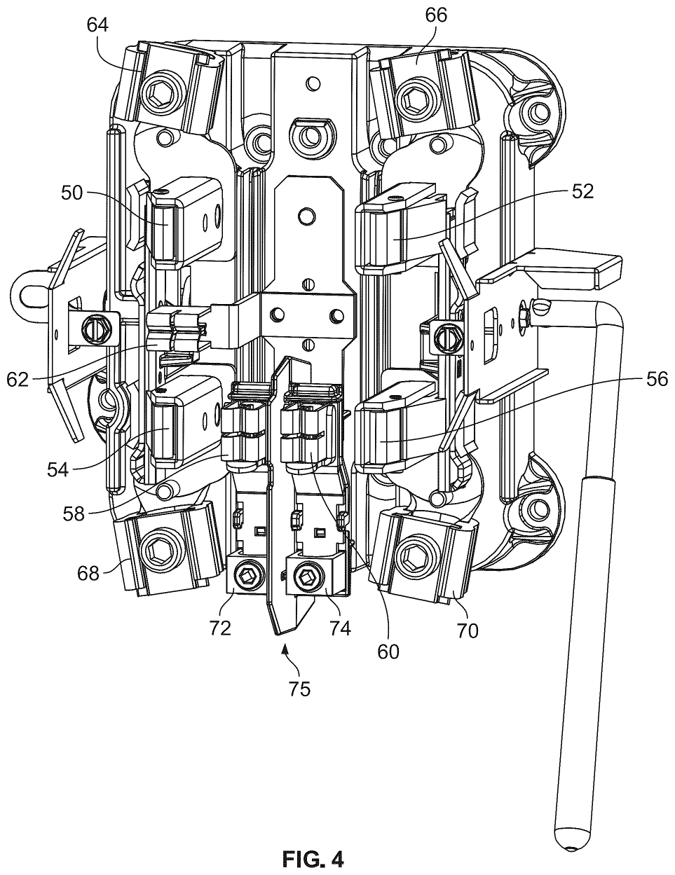

FIG. 4 shows the meter jaw block assembly 42 with the safety shield 46 removed. The meter jaw block assembly 42 includes the following meter jaws mounted to the insulating block 44: a first line meter jaw 50, a second line meter jaw 52, a first load meter jaw 54, a second load meter jaw 56, a first DER port meter jaw 58, a second DER port meter jaw 60, and another meter jaw 62 that may be used as a neutral reference. Each of the meter jaws 50, 52, 54, 56, 58, 60, and 62 is configured to receive a connector blade (not shown) extending from a rear of the meter 18 when the meter 18 is installed in the meter socket 10 as shown in FIG. 1.

The meter 18 may be an AMI (advanced metering infrastructure) meter that communicates with the electric power utility over an existing communication network, although other types of meters may also be used. The meter 18 may also be configured as a meter for use with a DER device, such as solar panels, wind turbines, or electric vehicle batteries. The meter 18 includes two upper connector blades received by the first and second line meter jaws 50 and 52, two lower connector blades received by the first and second load meter jaws 54 and 56, two DER port connector blades received by the first and second DER port meter jaws 58 and 60, and a neutral connector blade received by the meter jaw 62. The connector blades of the meter 18 are positioned to snap into the meter jaws 50, 52, 54, 56, 58, 60, and 62. The DER port connector blades are a parallel output path for the electrical power received by the meter (i.e., the electrical power received by the meter from the line side connector blades can be output by the meter through the DER port connector blades in parallel with the load side connector blades).

The meter jaw block assembly 42 further includes the following electrical connectors mounted to the insulating block 44: a first line electrical connector 64, a second line electrical connector 66, a first load electrical connector 68, a second load electrical connector 70, a first DER electrical connector 72, and a second DER electrical connector 74. The electrical connectors 64, 66, 68, 70, 72, and 74 are mechanically, electrically and thermally coupled to the meter jaws 50, 52, 54, 56, 58, and 60, respectively.

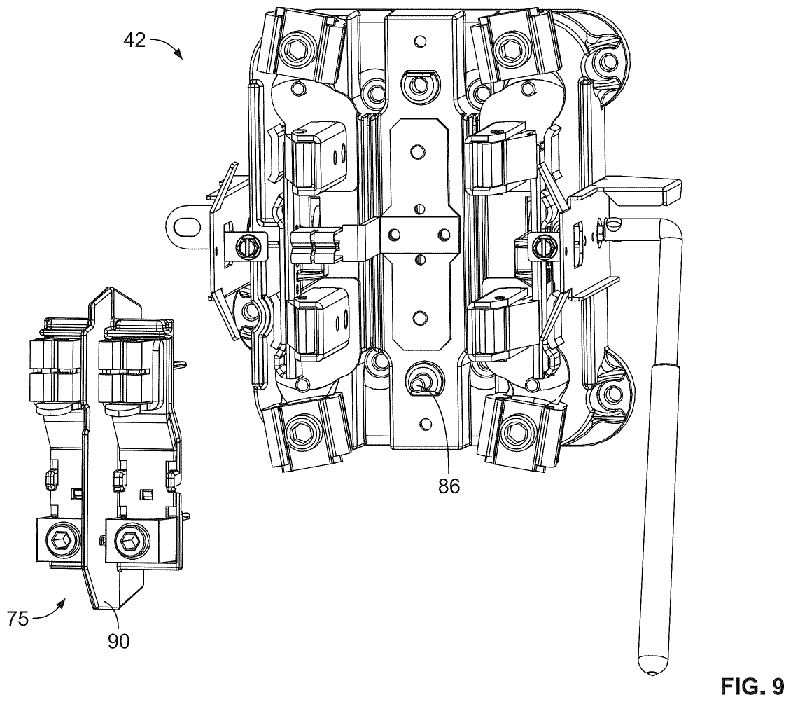

The first and second DER port meter jaws 58 and 60 and first and second DER electrical connectors 72 and 74 are part of a DER port jaw assembly 75, described in more detail below with reference to FIGS. 9-17.

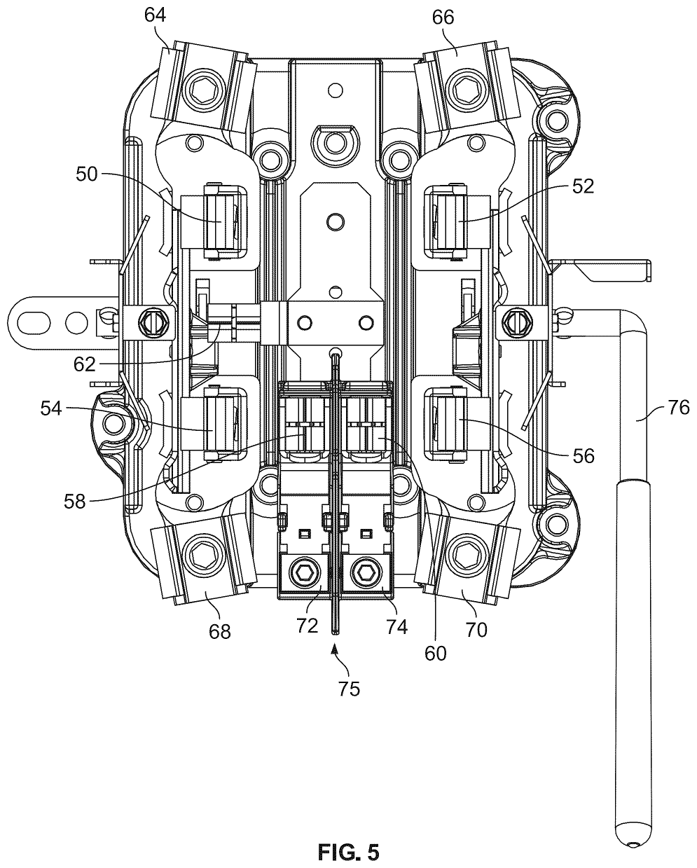

As shown in FIG. 5, the meter jaws 50 and 52 are spaced apart horizontally from each other across the insulating block 44 and are each positioned adjacent a top of the insulating block 44. The meter jaws 54 and 56 are spaced vertically below the meter jaws 50 and 52, respectively. The meter jaws 54 and 56 are spaced apart horizontally from each other across the insulating block 44 and are each positioned adjacent a bottom of the insulating block 44. The meter jaws 58 and 60 are positioned between the meter jaws 54 and 56 adjacent a bottom of the insulating block 44, such that the meter jaws 54, 56, 58, and 60 are generally horizontally aligned across the insulating block 44. The meter jaw 62 is positioned between the meter jaws 50 and 54. The electrical connectors 64 and 66 are positioned above the meter jaws 50 and 52, respectively. The electrical connectors 68 and 70 are positioned below the meter jaws 54 and 56, respectively. The electrical connectors 72 and 74 are positioned below the meter jaws 58 and 60, respectively.

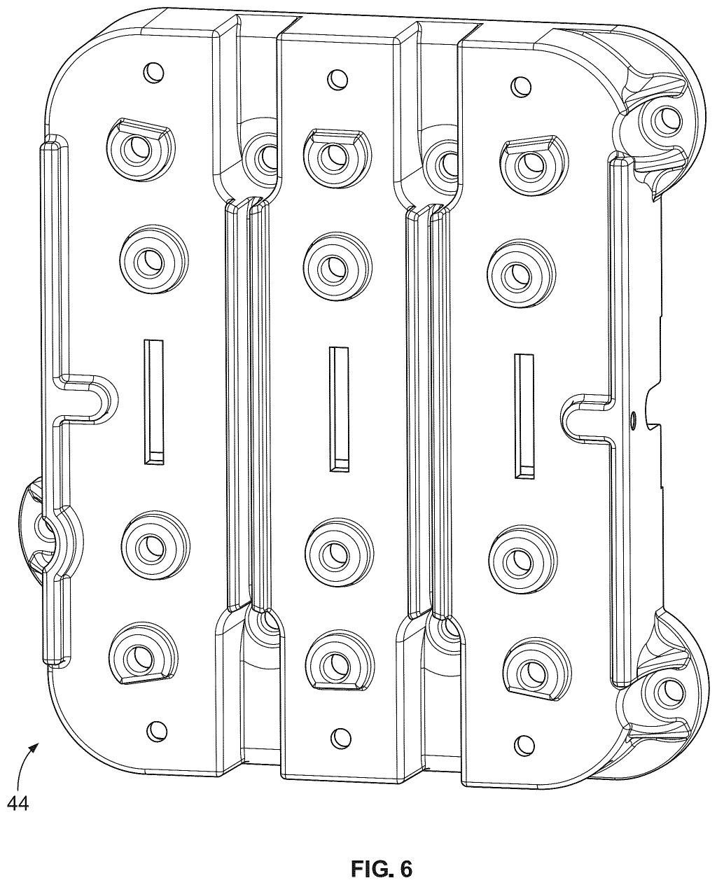

It can be appreciated that electric utility power is provided at first and second line electrical connectors 64 and 66, power to a customer or load is provided at first and second load electrical connectors 68 and 70, and power to or from a DER device is provided at first and second DER electrical connectors 72 and 74. Insulating block 44, shown in FIG. 6, functions to insulate the electrical connectors 64, 66, 68, 70, 72, and 74 from enclosure 12. The insulating block 44 is formed from a material that is an electrical insulator to electrically insulate the electrical connectors 64, 66, 68, 70, 72, and 74 from the enclosure 12. For example, the insulating block 44 may be formed from a thermosetting polymer or other type of suitable plastic material.

The meter jaw block assembly 42 includes a lever bypass 76 (FIG. 5) that may be used to bypass the meter 18 and connect the electrical connectors 64 and 68 together and the electrical connectors 66 and 70 together. For example, if the meter 18 is removed, the lever bypass 76 may be used to provide continuous power to a structure served by the meter socket 10.

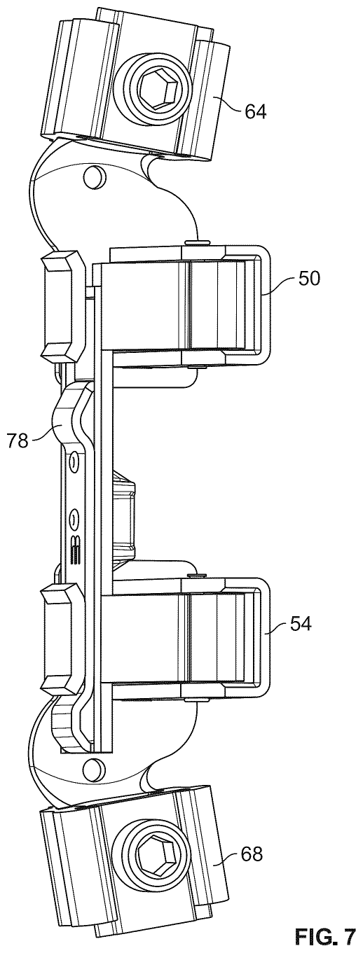

FIG. 7 shows the electrical connector 64 connected to the meter jaw 50 and the electrical connector 68 connected to the meter jaw 54. A slide 78 is shown that may interact with the lever bypass 76 to connect the meter jaws 50 and 54 and connect the electrical connectors 64 and 68.

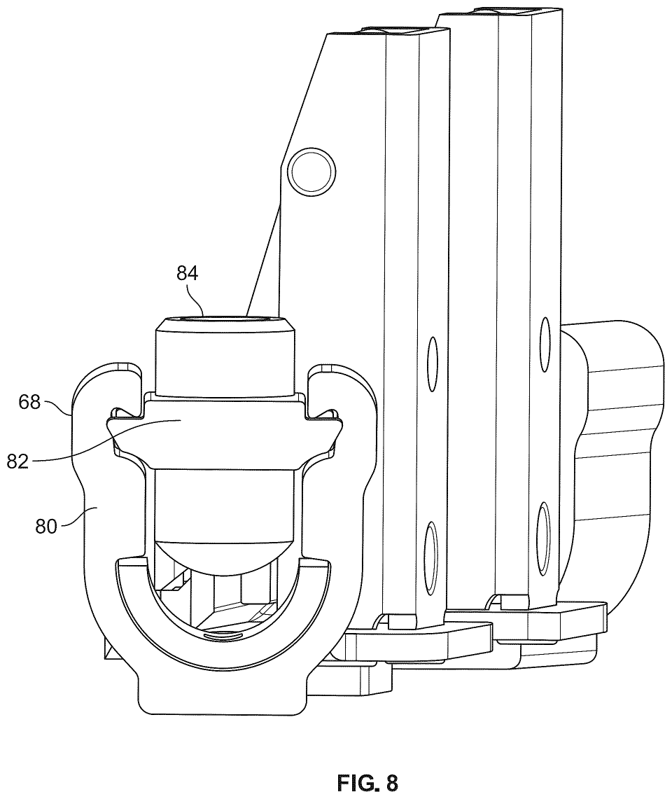

The electrical connector 68 is shown in more detail in FIG. 8. The electrical connector 68 includes a conductor receiver having a U-shaped receiver body 80, a slide nut 82, and a threaded slide screw 84. The conductor receiver has an inner surface that defines a channel sized to receive an end portion of a conductor. Tightening the slide screw 84 mechanically and electrically connects the conductor to the electrical connector 68. The electrical connectors 64, 66, and 70 have a similar structure as electrical connector 68.

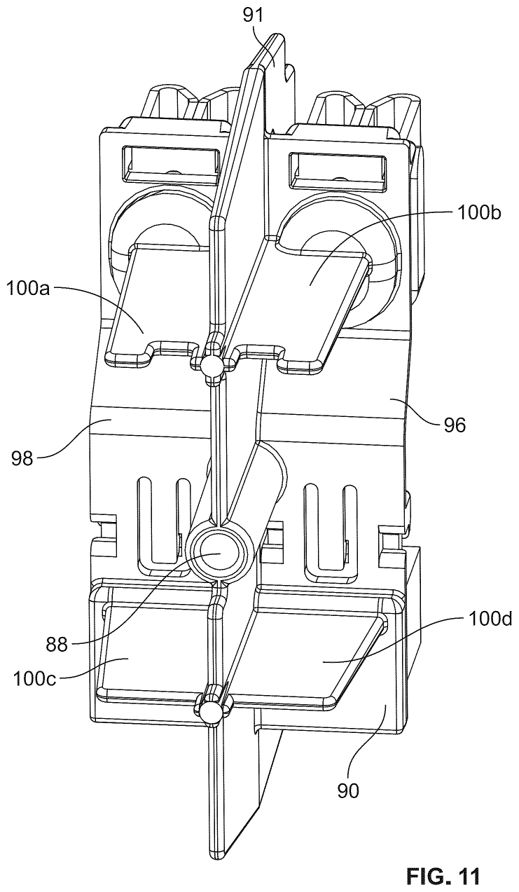

Referring to FIG. 9, the DER port jaw assembly 75 is shown removed from the remainder of the meter jaw block assembly 42. A fastener 86 (e.g., a screw) extending through the insulating block 44 from the rear of the insulating block 44 mounts the DER port jaw assembly 75 to the insulating block 44. The fastener 86 is received in a threaded opening 88 (FIG. 11) of a base 90 of the DER port jaw assembly 75. The base 90 is formed from a material that is an electrical insulator to electrically insulate the meter jaws 58 and 60 and the electrical connectors 72 and 74. The DER port jaw assembly 75 includes first and second bus bars 92 and 94. The first bus bar 92 electrically connects the meter jaw 58 to the electrical connector 72, and the second bus bar 94 electrically connects the meter jaw 60 to the electrical connector 74. In at least some embodiments, the base 90 may be integrally formed with the insulating block 44.

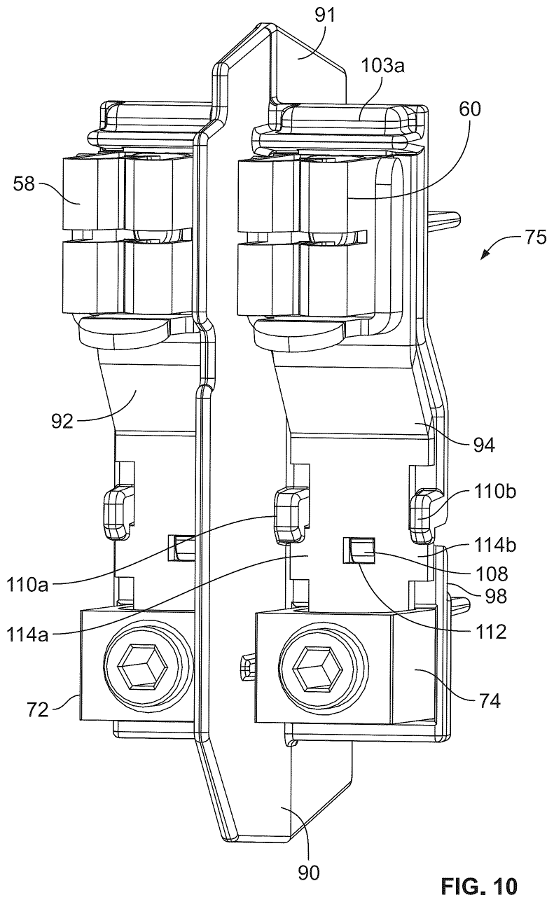

FIG. 11 shows the rear side of the base 90. The base 90 includes a divider 91 extending from a front to a rear of the base 90. The divider 91 is positioned between the meter jaws 58 and 60, as shown in FIG. 10, and between the electrical connectors 72 and 74. The threaded opening 88 is formed in a rear portion of the divider 91. First and second bus mounts 96 and 98 extend laterally outward from the divider 91. Supports 100a-d also extend laterally outward from the divider 91 behind the bus mounts 96 and 98.

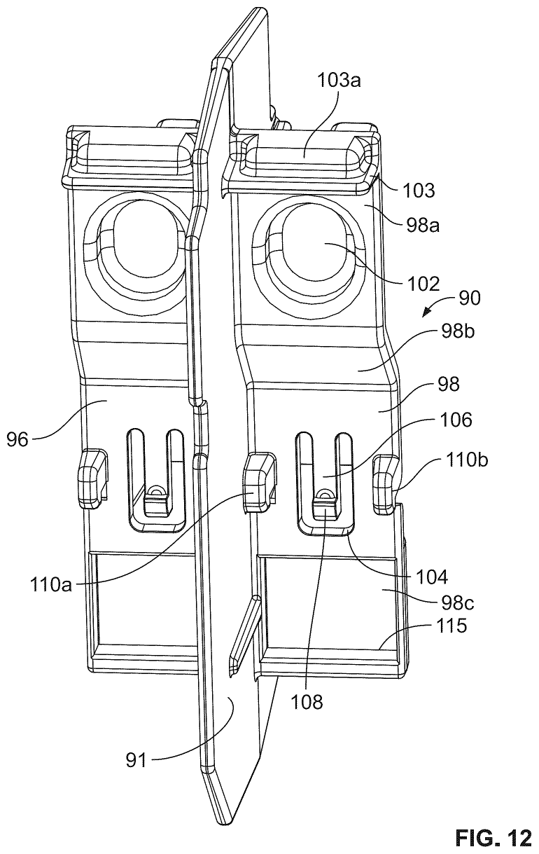

As shown in FIG. 12, the bus mounts 96 and 98 have a substantially similar structure. Accordingly, only bus mount 98 is described in detail herein. The bus mount 98 includes a first section 98a that is generally vertical, a second section 98b that extends downward and rearward at an angle from the first section 98a, and a third section 98c that generally extends vertically downward from the second section 98b. A recess 102 is formed in a center of the first section 98a. The recess 102 may receive a fastener of the meter jaw 60, as described in more detail below. An upper wall 103 with a receptacle 103a extends forward from a top of the first section 98a. The third section 98c includes an opening 104 with a tab 106 extending downward in the opening 104. The tab 106 is supported at its top end. A latch 108 extends outward from a bottom end of the tab 106. Hooks 110a and 110b extend outward from the third section 98c at both sides of the tab 106. The hooks 110a and 110b face downward to hook a portion of the bus bar 94 as the bus bar 94 moves upward when installed. Below the opening 104 is a recess 115 for receiving a portion of the electrical connector 74.

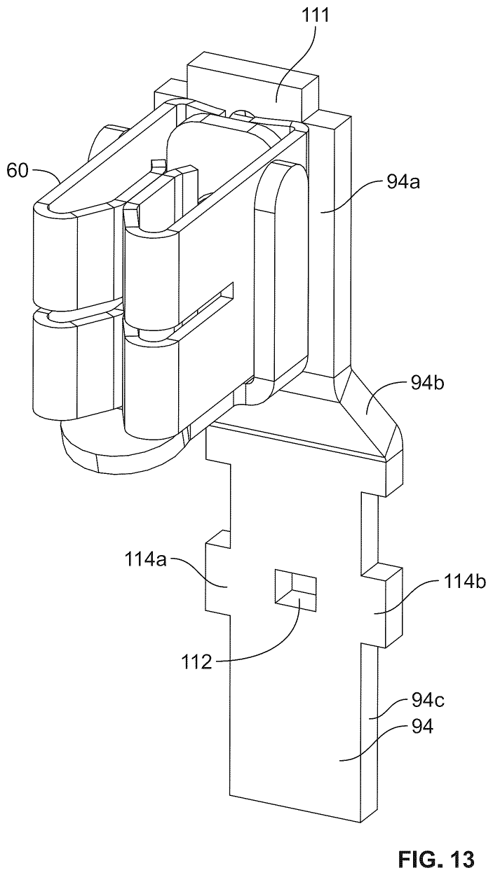

FIG. 13 shows the bus bar 94 connected to the meter jaw 60. The bus bar 92 and meter jaw 58 have a substantially similar structure as the bus bar 94 and meter jaw 60. Accordingly, only the bus bar 94 and meter jaw 60 are described in detail herein. The bus bar 94 includes a first section 94a that is generally vertical, a second section 94b that extends downward and rearward at an angle from the first section 94a, and a third section 94c that generally extends vertically downward from the second section 94b. The first, second, and third sections 94a-c of the bus bar 94 correspond with the first, second, and third sections 98a-c of the bus mount 98 so that the bus bar 94 can mount substantially flush to the bus mount 98, as shown in FIG. 10. The meter jaw 60 connects to the first section 94a of the bus bar, as described in more detail below. A tab 111 extends upward from a top wall of the first section 94a. The third section 94c of the bus bar 94 includes a central opening 112. The third section 94c further includes tabs 114a and 114b that extend laterally outward from side walls of the third section 94c.

When the bus bar 94 is mounted on the bus mount 98, as shown in FIG. 10, the latch 108 engages the surfaces surrounding the opening 112 in the bus bar 94 to prevent downward movement of the bus bar 94 with respect to the bus mount 98. The bus bar 94 is moved upward with respect to the bus mount 98 to install the bus bar 94, and as the bus bar 94 moves upward, the tab 106 (FIG. 12) may deflect rearward until the latch 108 is received by the opening 112, at which point the tab 106 moves forward to its normal position. The hooks 110a and 110b on the bus mount 98 receive the tabs 114a and 114b, respectively, on the bus bar 94 to prevent upward and forward movement of the bus bar 94 with respect to the bus mount 98. The receptacle 103a on the bus mount 98 receives the tab 111 on the bus bar 94 to also prevent upward and forward movement of the bus bar 94 with respect to the bus mount 98. In this manner, the bus bar 94 may be mounted to the bus mount 98 without the use of tools. Alternatively, the bus bar 94 may be mounted to the bus mount 98 by any other suitable means. For example, a fastener, such as a screw, may be used to mount the bus bar 94 to the bus mount 98.

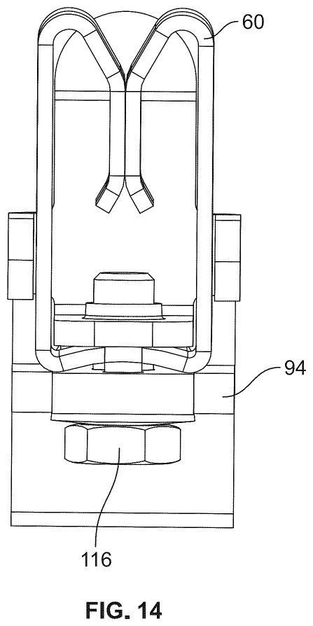

FIG. 14 shows the meter jaw 60 mounted to the bus bar with a fastener 116, which may be a screw that threadingly engages an opening in the meter jaw 60. The head of the fastener 116 may be received by the recess 102 (FIG. 12) in the bus mount 98 when the bus bar 94 is installed on the bus mount 98.

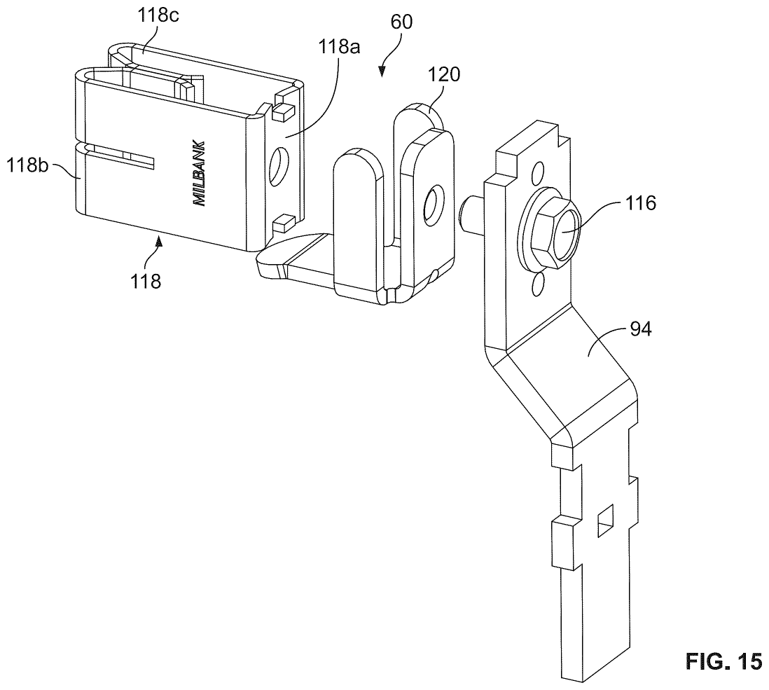

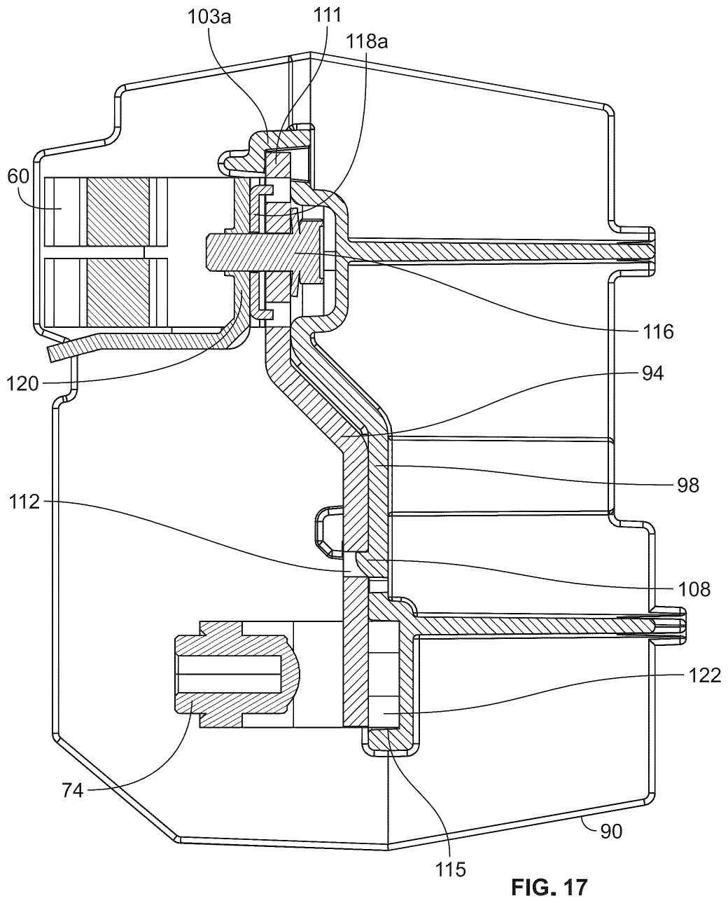

As shown in FIG. 15, the meter jaw 60 includes a base 118a with a pair of resilient meter jaw contacts 118b and 118c extending therefrom. Meter jaw contacts 118b and 118c define a space between for receiving the connector blade of meter 18 (FIG. 1). Meter jaw 118 is mechanically, electrically and thermally coupled to bus bar 94 by the fastener 116, which engages a threaded opening in a jaw nut 120. The base 118a of the meter jaw 60 is positioned between the bus bar 94 and a portion of the jaw nut 120, as shown in FIG. 17.

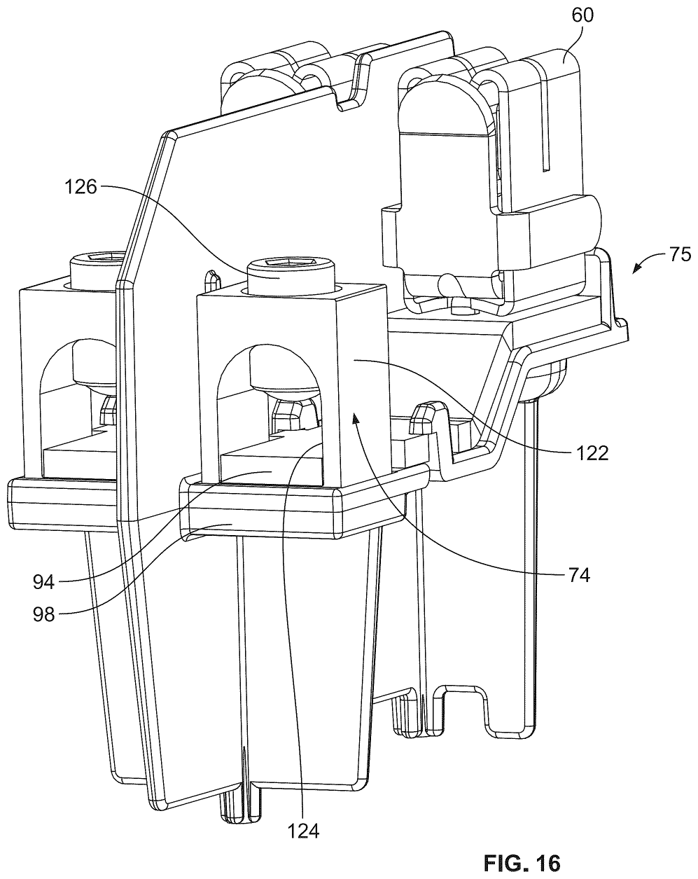

FIG. 16 shows the electrical connector 74 with a housing 122 that is mounted to the bus mount 98 and bus bar 94. The housing 122 has an opening 124 for receiving a conductor. A threaded opening at a front of the housing 122 receives a screw 126. Tightening the screw 126 with a conductor in the opening 124 mechanically and electrically connects the conductor to the electrical connector 74 and bus bar 94.

FIG. 17 is a cross-sectional view that shows the latch 108 received in the opening 112 of the bus bar 94 and the tab 111 received in the receptacle 103a. Further, FIG. 17, shows a rear wall of the housing 122 received within the recess 115 of the bus mount 98. The portion of the housing 122 in the recess 115 is positioned between the bus mount 98 and the bus bar 94 to securely mount the housing 122 to the bus mount 98 when the bus bar 94 is mounted to the bus mount 98.

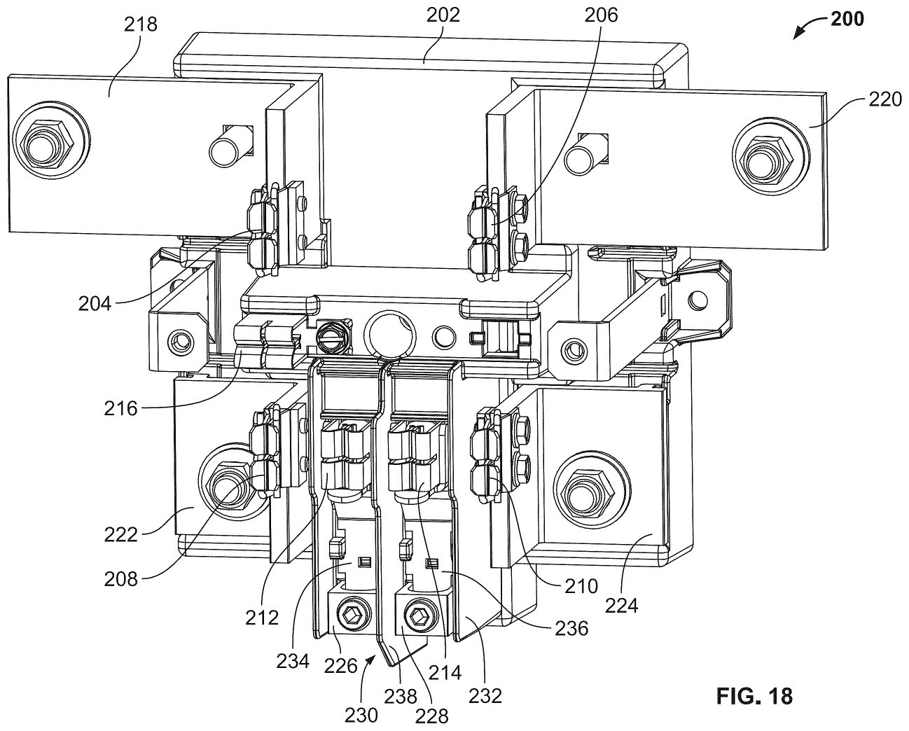

FIG. 18 shows a second embodiment of meter jaw block assembly 200 that may be used with the meter socket enclosure 12 shown in FIG. 1. The meter jaw block assembly 200 may be configured for use in accordance with EUSERC standards. The meter jaw block assembly 200 includes an insulating block 202. Mounted to the insulating block 202 are a first line meter jaw 204, a second line meter jaw 206, a first load meter jaw 208, a second load meter jaw 210, a first DER port meter jaw 212, a second DER port meter jaw 214, and another meter jaw 216 that may be used as a neutral reference. Also mounted to the insulating block 202 are a first line electrical connector 218, a second line electrical connector 220, a first load electrical connector 222, a second load electrical connector 224, a first DER electrical connector 226, and a second DER electrical connector 228. The first and second DER port meter jaws 212 and 214 and the first and second DER electrical connectors 226 and 228 are part of a DER port jaw assembly 230. The DER port jaw assembly 230 includes a base 232 mounted to the insulating block 202 and first and second bus bars 234 and 236 that connect the first and second DER port meter jaws 212 and 214 and the first and second DER electrical connectors 226 and 228 in a similar manner as described above with respect to DER port jaw assembly 75. The portion of the base 232 to which the bus bars 234 and 236 mount is substantially similar to the base of the DER port jaw assembly 75. The bus bars 234 and 236 mount to the base 232 in substantially the same manner as described above with respect to DER port jaw assembly 75. The base 232 includes a divider 238 that is positioned between the first and second DER port meter jaws 212 and 214 and between the first and second DER electrical connectors 226 and 228. In at least some embodiments, the base 232 may be formed integrally with the insulating block 202.

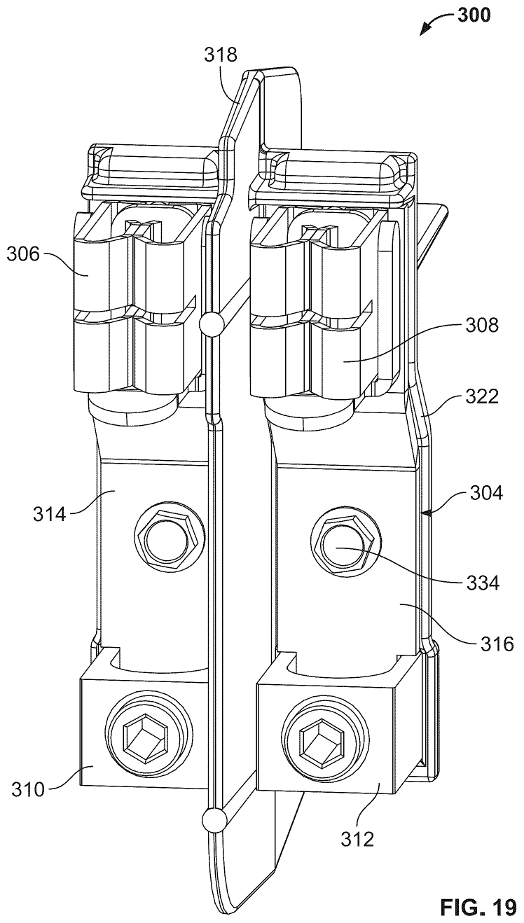

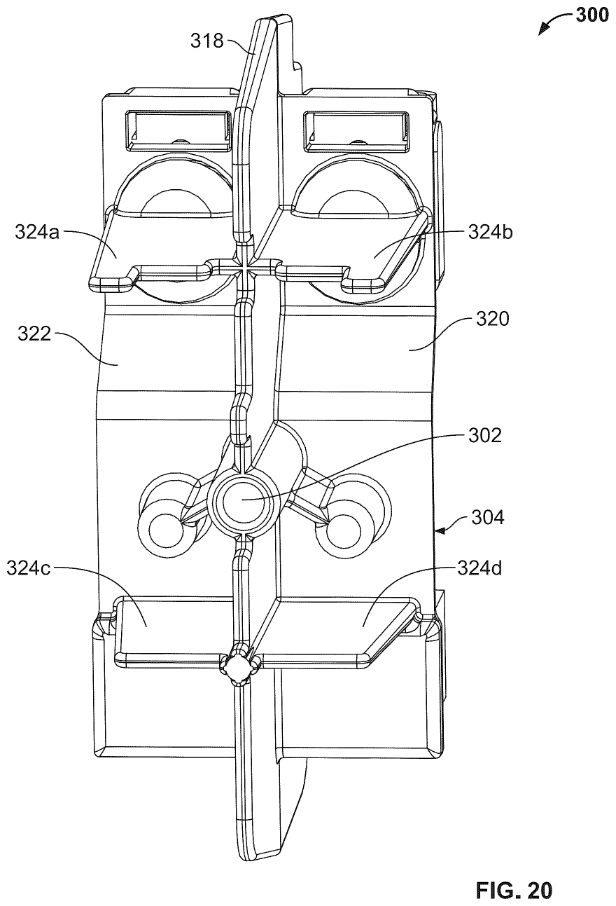

FIGS. 19-23 show an alternative embodiment of DER port jaw assembly 300 that may be used with the meter jaw block assembly 42, shown in FIGS. 2-9, as a substitute for the DER port jaw assembly 75. The fastener 86 shown in FIG. 9 may be used to mount the DER port jaw assembly 300 to the insulating block 44. The fastener 86 is received in a threaded opening 302 (FIG. 20) of a base 304 of the DER port jaw assembly 300. As shown in FIG. 19, the DER port jaw assembly 300 includes first and second DER port meter jaws 306 and 308, and first and second DER electrical connectors 310 and 312 that are structured and operate in a substantially similar manner as described above with respect to first and second DER port meter jaws 58 and 60 and first and second DER electrical connectors 72 and 74. The base 304 is formed from a material that is an electrical insulator to electrically insulate the meter jaws 306 and 308 and the electrical connectors 310 and 312. The DER port jaw assembly 300 includes first and second bus bars 314 and 316. The first bus bar 314 electrically connects the meter jaw 306 to the electrical connector 310, and the second bus bar 316 electrically connects the meter jaw 308 to the electrical connector 312. In at least some embodiments, the base 304 may be integrally formed with the insulating block 44.

FIG. 20 shows the rear side of the base 304. The base 304 includes a divider 318 extending from a front to a rear of the base 304. The divider 318 is positioned between the meter jaws 306 and 308, as shown in FIG. 19, and between the electrical connectors 310 and 312. The threaded opening 302 is formed in a rear portion of the divider 318. First and second bus mounts 320 and 322 extend laterally outward from the divider 318. Supports 324a-d also extend laterally outward from the divider 318 behind the bus mounts 320 and 322.

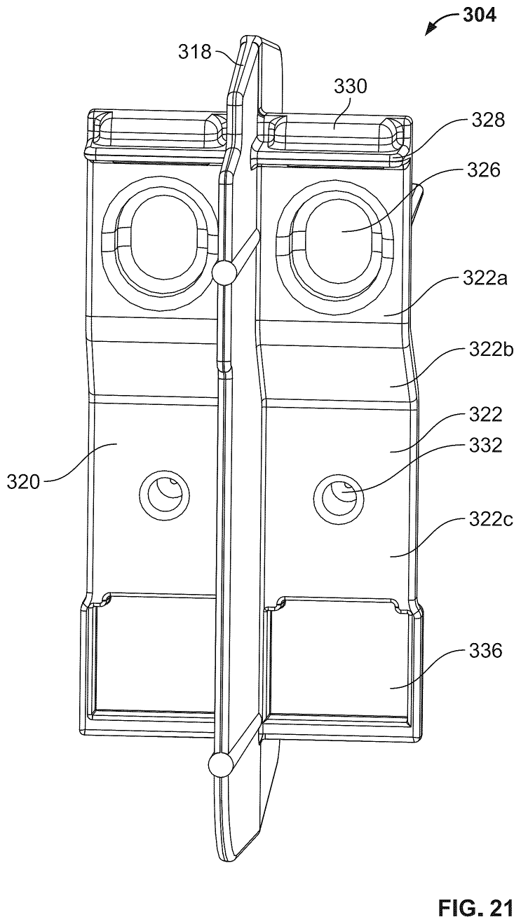

As shown in FIG. 21, the bus mounts 320 and 322 have a substantially similar structure. Accordingly, only bus mount 322 is described in detail herein. The bus mount 322 includes a first section 322a that is generally vertical, a second section 322b that extends downward and rearward at an angle from the first section 322a, and a third section 322c that generally extends vertically downward from the second section 322b. A recess 326 is formed in a center of the first section 322a. The recess 326 may receive a fastener of the meter jaw 308, as described in more detail below. An upper wall 328 with a receptacle 330 extends forward from a top of the first section 322a. The third section 322c includes a threaded opening 332 that receives a fastener 334 (FIG. 19) for mounting the second bus bar 316 to the bus mount 322. Below the opening 332 is a recess 336 for receiving a portion of the electrical connector 312.

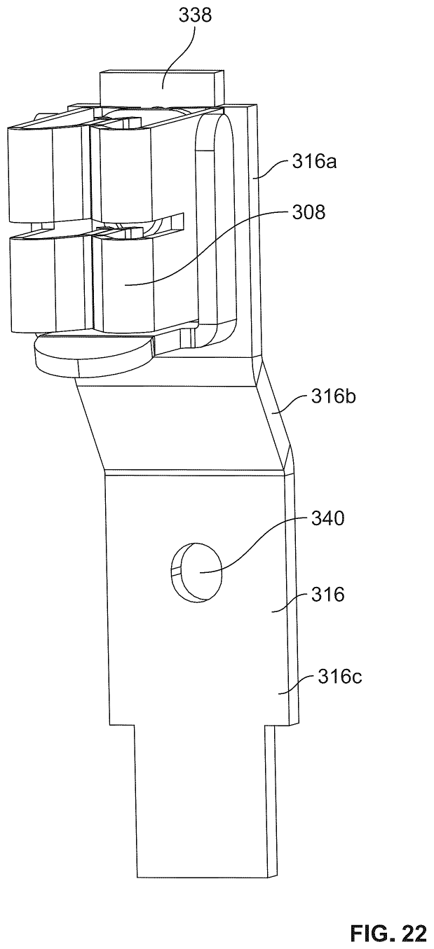

FIG. 22 shows the bus bar 316 connected to the meter jaw 308. The bus bar 314 and meter jaw 306 have a substantially similar structure as the bus bar 316 and meter jaw 308. Accordingly, only the bus bar 316 and meter jaw 308 are described in detail herein. The bus bar 316 includes a first section 316a that is generally vertical, a second section 316b that extends downward and rearward at an angle from the first section 316a, and a third section 316c that generally extends vertically downward from the second section 316b. The first, second, and third sections 316a-c of the bus bar 316 correspond with the first, second, and third sections 322a-c of the bus mount 322 so that the bus bar 316 can mount substantially flush to the bus mount 322, as shown in FIG. 19. The meter jaw 308 may be connected to the first section 316a of the bus bar 316 in the same manner as shown in FIG. 14 with respect to meter jaw 60 and bus bar 94. A tab 338 extends upward from a top wall of the first section 316a. The third section 316c of the bus bar 316 includes a central opening 340.

When the bus bar 316 is mounted on the bus mount 322, as shown in FIG. 19, the fastener 334 extends through the central opening 340 in the bus bar 316 and engages the threaded opening 332 (FIG. 21) in the bus mount 322. The receptacle 330 on the bus mount 322 receives the tab 338 on the bus bar 316.

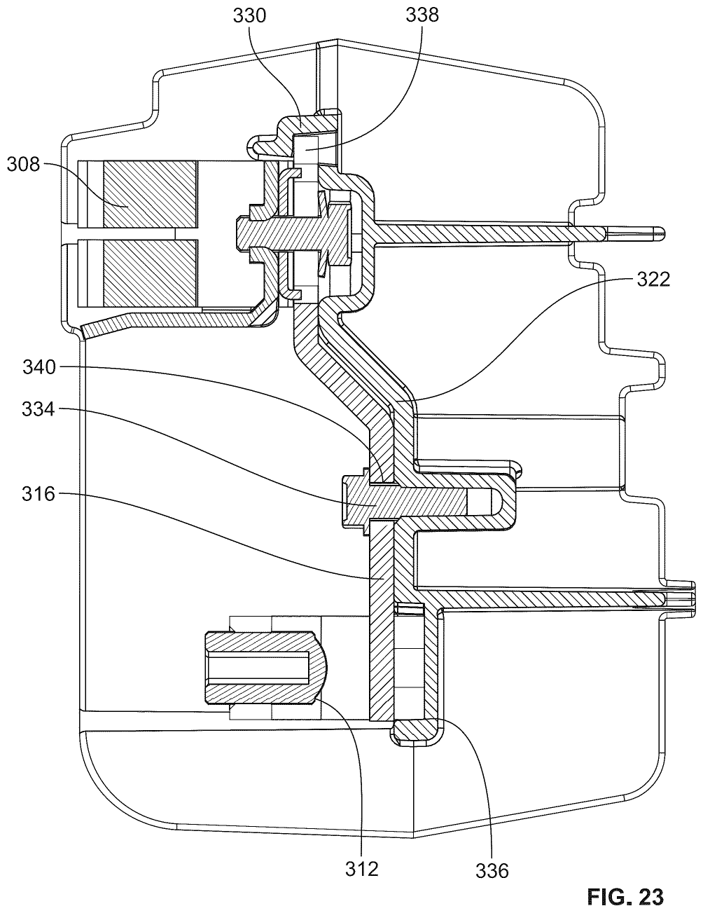

FIG. 23 is a cross-sectional view that shows the fastener 334 received in the opening 340 of the bus bar 316 and the tab 338 received in the receptacle 330. Further, FIG. 17, shows a rear portion of the electrical connector 312 received within the recess 336 of the bus mount 322. The portion of the electrical connector 312 in the recess 336 is positioned between the bus mount 322 and the bus bar 316 to securely mount the electrical connector 312 to the bus mount 322 when the bus bar 316 is mounted to the bus mount 322.

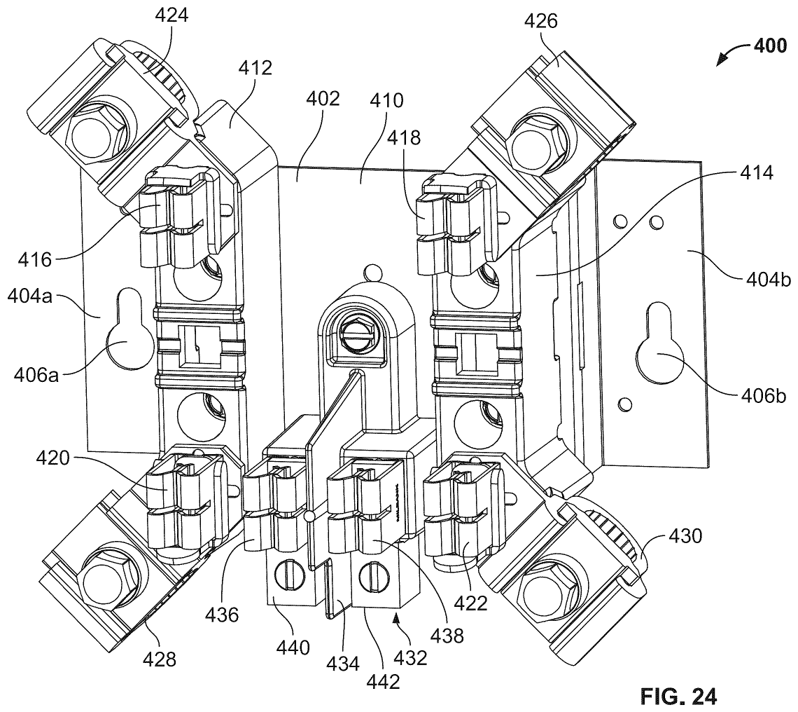

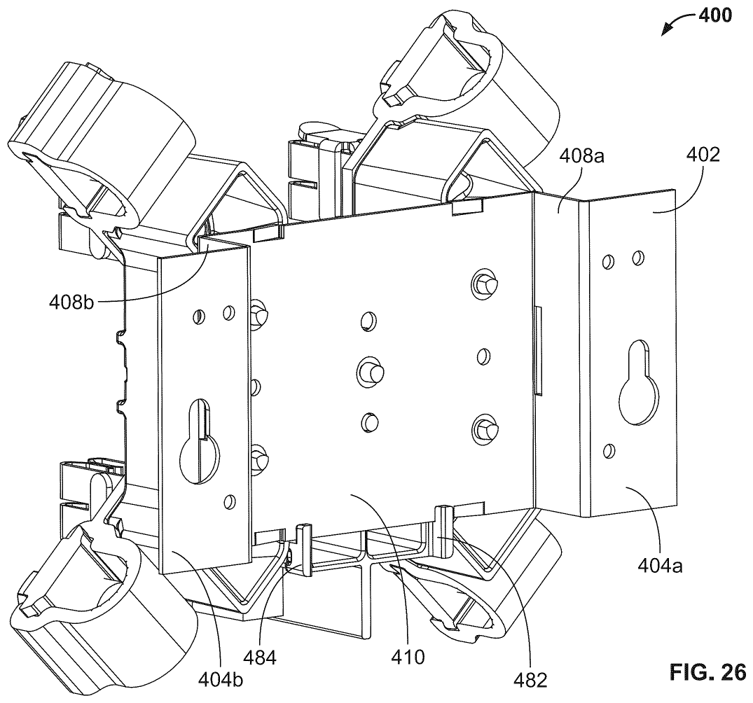

FIGS. 24-34 show an alternative embodiment of meter jaw block assembly 400 that may be used with the meter socket enclosure 12 shown in FIG. 1. The meter jaw block assembly 400 includes a riser structure 402 that may be mounted to the back wall 24 (FIG. 1) of the meter socket enclosure 12 inside of the enclosure. The riser structure 402 has a pair of mounting walls 404a-b on opposite sides of the riser structure 402. Each mounting wall 404a-b includes an opening 406a-b, respectively, to receive a fastener to secure the riser structure 402 to the back wall 24. Side walls 408a-b (FIG. 26) extend forwardly outward from mounting walls 404a-b, respectively, and a planar front wall 410 extends between side walls 408a-b. The side walls 408a-b space the front wall 410 from back wall 24. The spacing of the front wall 410 from back wall 24 is chosen to properly position insulating blocks 412 and 414 (shown in FIG. 24) in relation to back wall 24.

The meter jaw block assembly 400 includes a first insulating block 412 secured to the front wall 410 of riser structure 402 and a second insulating block 414 secured to the front wall 410 of riser structure 402. The meter jaw block assembly 400 includes the following meter jaws mounted to the insulating blocks 412 and 414: a first line meter jaw 416, a second line meter jaw 418, a first load meter jaw 420, and a second load meter jaw 422.

The meter jaw block assembly 400 further includes the following electrical connectors mounted to the insulating blocks 412 and 414: a first line electrical connector 424, a second line electrical connector 426, a first load electrical connector 428, and a second load electrical connector 430.

A DER port jaw assembly 432 includes a base 434 that is mounted to the front wall 410 of the riser structure 402. The DER port jaw assembly 432 includes a first DER port meter jaw 436, a second DER port meter jaw 438, a first DER electrical connector 440, and a second DER electrical connector 442.

Each of the meter jaws 416, 418, 420, 422, 436, and 438 is configured to receive a connector blade (not shown) extending from a rear of the meter 18 when the meter 18 is installed in the meter socket 10 as shown in FIG. 1. The meter jaws 416, 418, 420, 422, 436, and 438 of the meter jaw block assembly 400 may operate with meter 18 (FIG. 1) in the same manner as described above with respect to the meter jaws of the meter jaw block assembly 42. The electrical connectors 424, 426, 428, 430, 440, and 442 are mechanically, electrically and thermally coupled to the meter jaws 416, 418, 420, 422, 436, and 438, respectively.

As shown in FIG. 5, the meter jaws 416 and 418 are spaced apart horizontally from each other and are each positioned adjacent tops of the insulating blocks 412 and 414. The meter jaws 420 and 422 are spaced vertically below the meter jaws 416 and 418, respectively. The meter jaws 420 and 422 are spaced apart horizontally from each other and are each positioned adjacent bottoms of the insulating blocks 412 and 414. The meter jaws 436 and 438 are positioned between the meter jaws 420 and 422 adjacent bottoms of the insulating blocks 412 and 414, such that the meter jaws 420, 422, 436, and 438 are generally horizontally aligned. The electrical connectors 424 and 426 are positioned above and laterally outward from the meter jaws 416 and 418, respectively. The electrical connectors 428 and 430 are positioned below and laterally outward from the meter jaws 420 and 422, respectively. The electrical connectors 440 and 442 are positioned below the meter jaws 436 and 438, respectively.

It can be appreciated that electric utility power is provided at first and second line electrical connectors 424 and 426, power to a customer or load is provided at first and second load electrical connectors 428 and 430, and power to or from a DER device is provided at first and second DER electrical connectors 440 and 442. Insulating blocks 412 and 414 function to insulate the electrical connectors 424, 426, 428, 430, 440, and 442 from the riser structure 402 and enclosure 12. The insulating blocks 412 and 414 are formed from a material that is an electrical insulator to electrically insulate the electrical connectors 424, 426, 428, 430, 440, and 442 from the enclosure 12. For example, the insulating blocks 412 and 414 may be formed from a thermosetting polymer or other type of suitable plastic material.

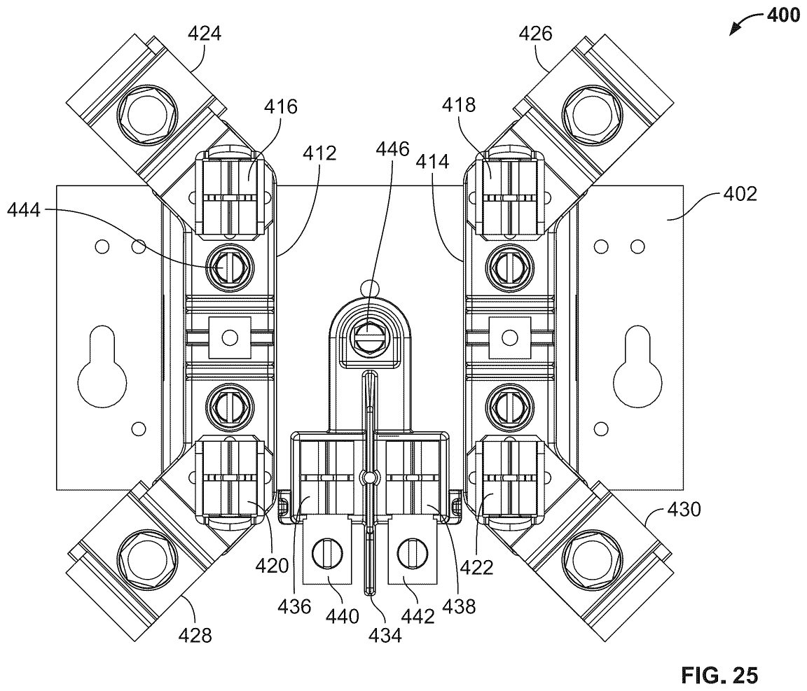

As shown in FIG. 25, the insulating blocks 412 and 414 are mounted to the riser structure 402 with screws, one of which is identified as 444. The screws 444 engage threaded openings (not shown) in the riser structure 402. The base 434 of the DER port jaw assembly 432 is also mounted to the riser structure 402 with a screw 446 that engages a threaded opening in the riser structure 402.

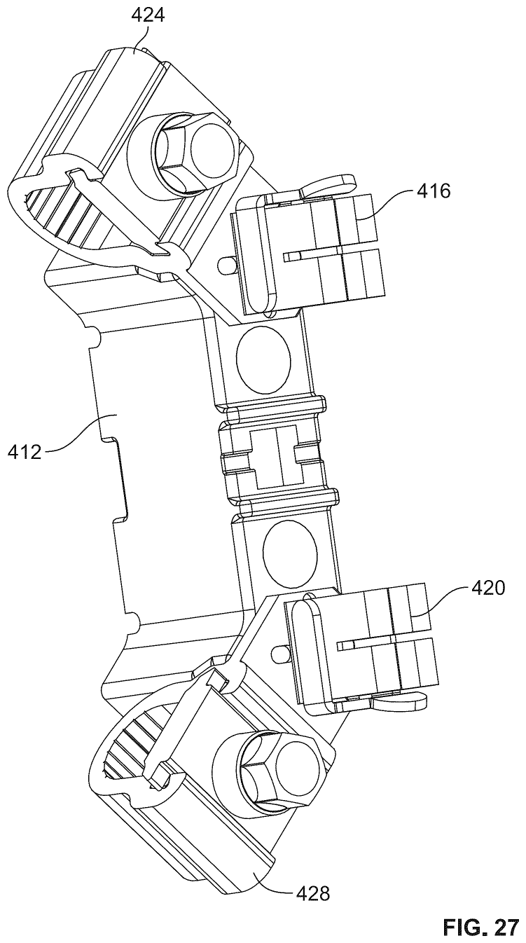

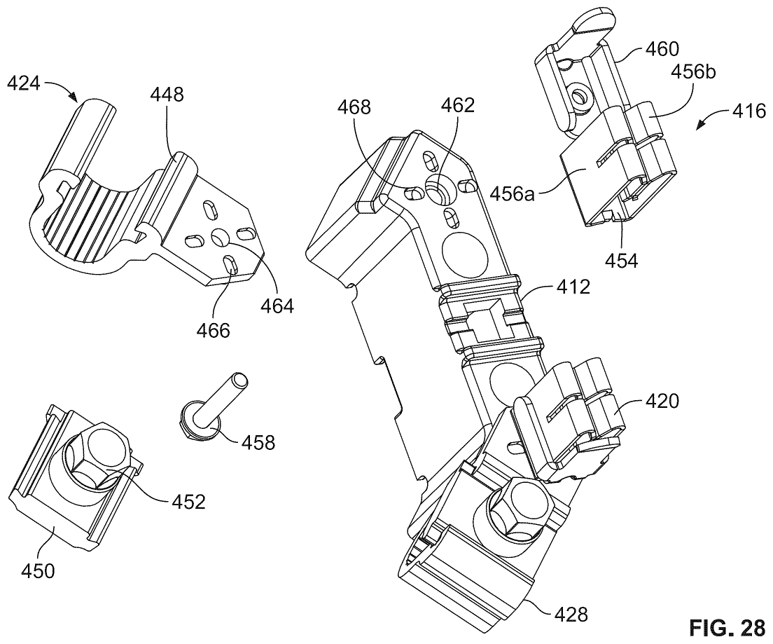

Referring to FIGS. 27 and 28, as described above, the first insulating block 412 mounts meter jaws 416 and 420 and electrical connectors 424 and 428. As shown in FIG. 28, the electrical connector 424 includes a conductor receiver having a U-shaped receiver body 448, a slide nut 450, and a threaded slide screw 452. The conductor receiver has an inner surface that defines a channel sized to receive an end portion of one of the power supply conductors. The meter jaw 416 includes a base 454 with a pair of resilient meter jaw contacts 456a-b extending therefrom. Meter jaw contacts 456a-b define a space between for receiving a connector blade (not shown) of meter 18 (FIG. 1). The meter jaw 416 is mechanically, electrically and thermally coupled to receiver body 448 by a bolt 458 and a jaw nut 460. Bolt 458 extends through a hole 462 in insulating block 412 from the back side to the front side and through a hole 464 in receiver body 448 and a hole (not shown) in meter jaw 416 before it is pushed or threaded into jaw nut 460 to secure the electrical connector 424 and meter jaw 416 to insulating block 412. Protrusions, one of which is identified as 466, extending from receiver body 448 are received by recesses, one of which is identified as 468, formed in insulating block 412 to further align and secure electrical connector 424 and meter jaw 416 to insulating block 412.

Electrical connector 428 and meter jaw 420 have structures that are substantially the same as electrical connector 424 and meter jaw 416, and electrical connector 428 and meter jaw 420 attach to insulating block 412 in substantially the same manner as electrical connector 424 and meter jaw 416. Accordingly, electrical connector 428 and meter jaw 420 are not described in detail herein. Likewise, the insulating block 414, meter jaws 418 and 422, and electrical connectors 426 and 430 have a substantially similar structure as the insulating block 412, electrical connectors 424 and 428 and meter jaws 416 and 420.

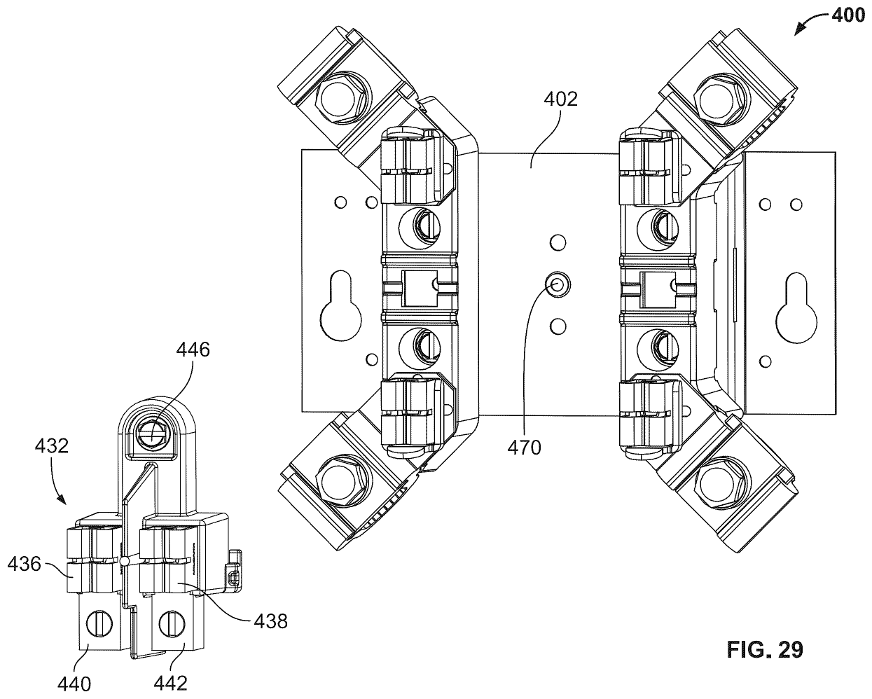

Referring to FIG. 29, the DER port jaw assembly 432 is shown removed from the remainder of the meter jaw block assembly 400. The fastener 446 (e.g., a screw) extends through an opening of the DER port jaw assembly 432 to mount the DER port jaw assembly 432 to the riser structure 402. The fastener 446 is received in a threaded opening 470 (FIG. 11) of the riser structure 402. The base 434 of the DER port jaw assembly 432 is formed from a material that is an electrical insulator to electrically insulate the meter jaws 436 and 438 and the electrical connectors 440 and 442.

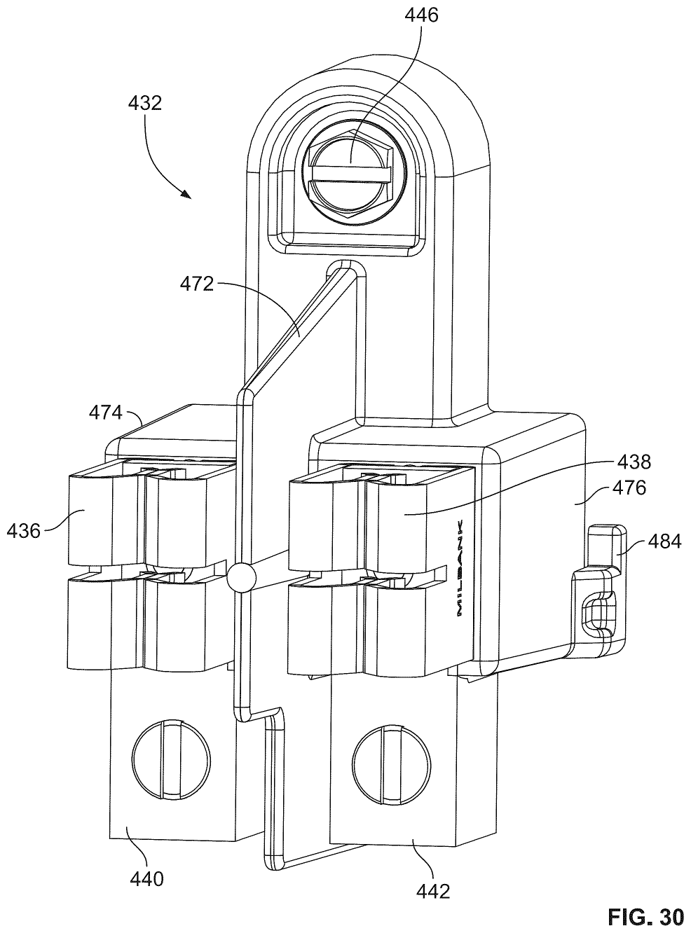

FIG. 30 shows the meter jaws 436 and 438 of the DER port jaw assembly 432 separated by a divider 472 of the base 434. The divider 472 is positioned between the meter jaws 436 and 438 and between the electrical connectors 440 and 442. First and second bus mounts 474 and 476 extend laterally outward from the divider 472.

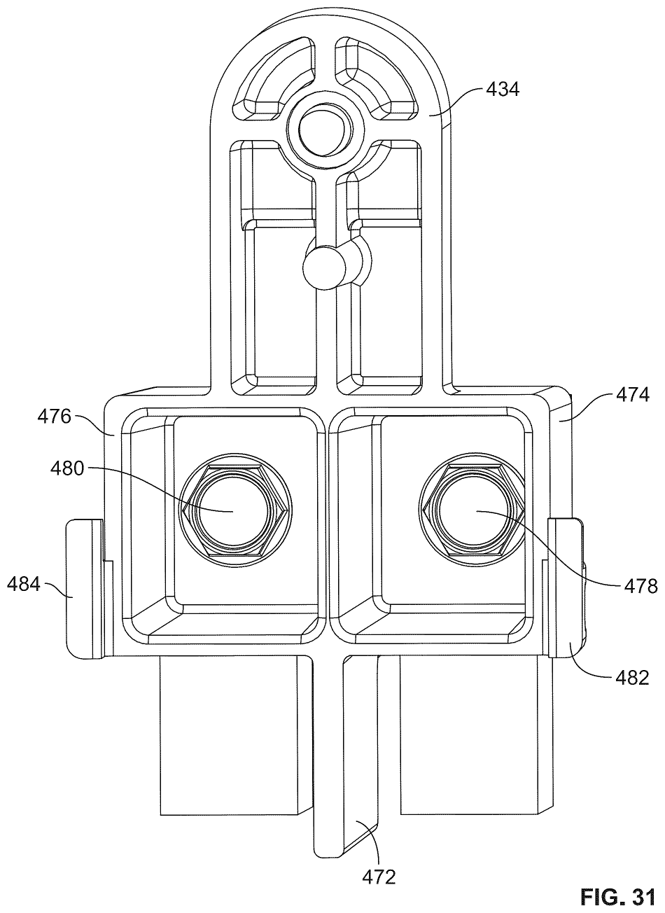

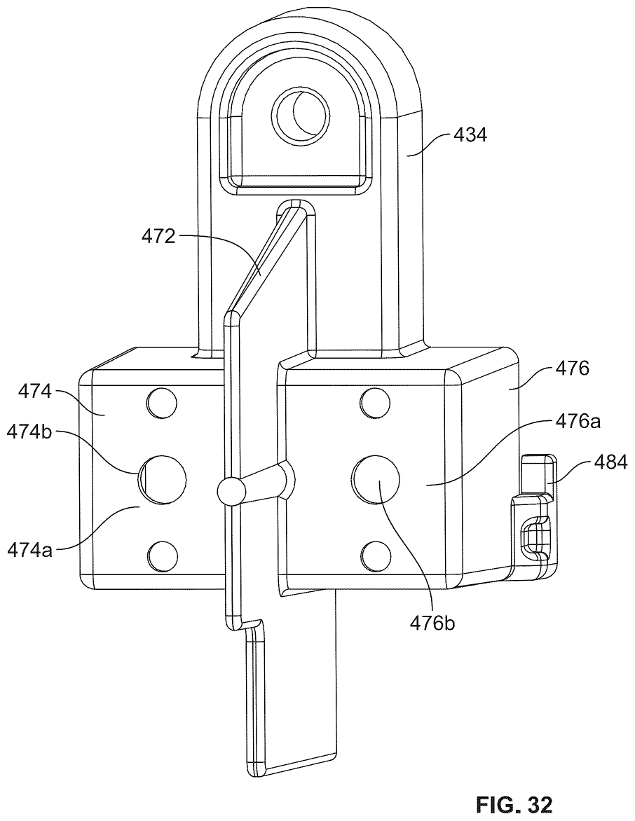

As shown in FIG. 32, the bus mounts 474 and 476 have planar surfaces 474a and 476a extending laterally outward from the divider 472. The planar surfaces 474a and 476a define openings 474b and 476b. Fasteners 478 and 480, shown in FIG. 31, extend through the openings 474b and 476b from the rear of the base 434. The fasteners 478 and 480 mount the meter jaws 436 and 438 and electrical connectors 440 and 442 to the base 434. Hooks 482 and 484 extending from the rear of the bus mounts 474 and 476, respectively, engage a lower portion of the riser structure 402, as shown in FIG. 26, to assist in mounting the base 434 to the riser structure 402.

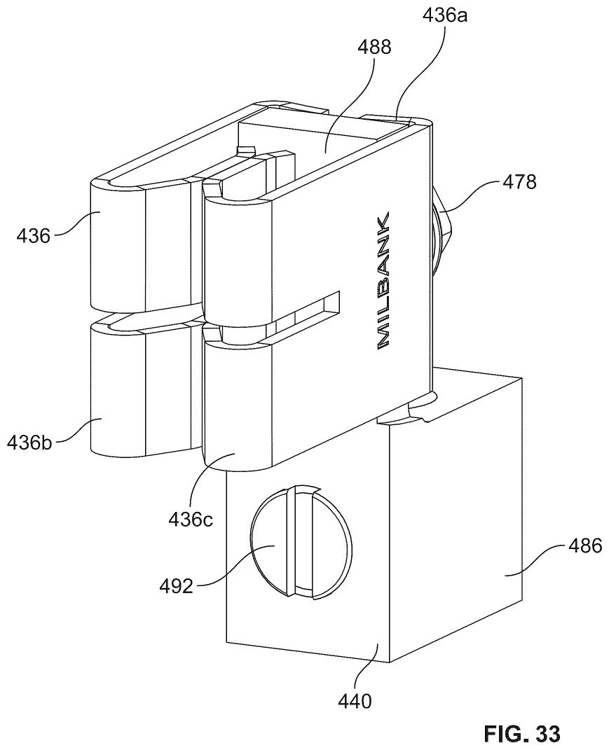

As shown in FIG. 33, the meter jaw 436 includes a base 436a with a pair of resilient meter jaw contacts 436b and 436c extending therefrom. Meter jaw contacts 436b and 436c define a space between for receiving the connector blade of meter 18 (FIG. 1). Meter jaw 436 is mechanically, electrically and thermally coupled to electrical connector 440 by the fastener 478, which engages a threaded opening in the electrical connector 440. The base 436a of the meter jaw 436 is positioned between the surface 474a (FIG. 32) of the base 434 and a portion of the electrical connector 440.

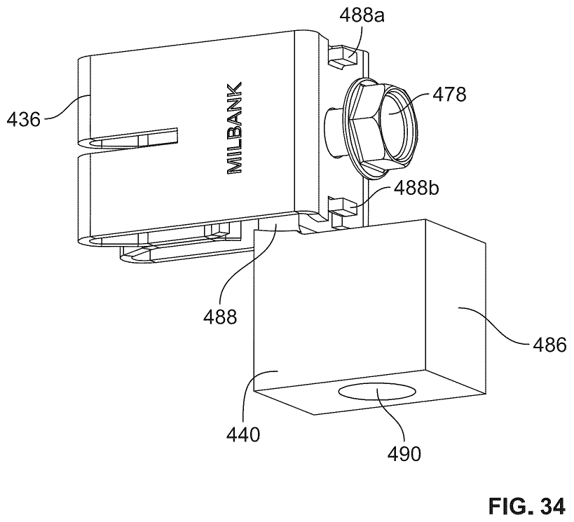

As shown in FIGS. 33 and 34, the electrical connector 440 has a housing 486 and a tab 488 extending upward from the housing 486. The tab 488 extends upward into the meter jaw 436 and has a threaded opening for receiving the fastener 478. Protrusions 488a-b extending rearward from the tab 488 are positioned in slots of the meter jaw 436 to securely retain the meter jaw 436 to the electrical connector 440 when the fastener 478 is tightened. The housing 486 has an opening 490 (FIG. 34) for receiving a conductor. A threaded opening at a front of the housing 486 receives a screw 492 (FIG. 33). Tightening the screw 492 with a conductor in the opening 490 mechanically and electrically connects the conductor to the electrical connector 440 and meter jaw 436. The tab 488 acts as a bus bar mounted to the base 434 to electrically connect the meter jaw 436 to the electrical connector 440.

The description set forth above provides several exemplary embodiments of the inventive subject matter. Although each exemplary embodiment represents a single combination of inventive elements, the inventive subject matter is considered to include all possible combinations of the disclosed elements. Thus, if one embodiment comprises elements A, B, and C, and a second embodiment comprises elements B and D, then the inventive subject matter is also considered to include other remaining combinations of A, B, C, or D, even if not explicitly disclosed.

The use of any and all examples or exemplary language (e.g., “such as”) provided with respect to certain embodiments is intended merely to better describe the invention and does not pose a limitation on the scope of the invention. No language in the description should be construed as indicating any non-claimed element essential to the practice of the invention.

The use of relative relational terms, such as first and second, top and bottom, and left and right, are used solely to distinguish one unit or action from another unit or action without necessarily requiring or implying any actual such relationship or order between such units or actions.

In addition, the recitation of ranges of values in this disclosure is merely intended to serve as a shorthand method of referring individually to each separate value falling within the range. Unless otherwise indicated, each individual value is incorporated into the disclosure as if it were individually recited herein.

The use of the terms “comprises,” “comprising,” or any other variation thereof, are intended to cover a non-exclusive inclusion, such that a system or method that comprises a list of elements does not include only those elements, but may include other elements not expressly listed or inherent to such system or method.

While the present invention has been described and illustrated hereinabove with reference to several exemplary embodiments, it should be understood that various modifications could be made to these embodiments without departing from the scope of the invention. Therefore, the present invention is not to be limited to the specific configurations or methodologies of the exemplary embodiments, except insofar as such limitations are included in the following claims.

What is claimed and desired to be secured by Letters Patent is as follows:

1. A DER port jaw assembly for use with a meter socket comprising:
a base;
a bus bar mounted to the base;
a DER port meter jaw mounted to the base and electrically coupled to the bus bar; and
a DER electrical connector mounted to the base and electrically coupled to the bus bar.

2. The DER port jaw assembly of claim 1, wherein the base comprises a divider and first and second bus mounts extending laterally outward from the divider.

3. The DER port jaw assembly of claim 2, wherein each of the bus bar, the DER port meter jaw, and the DER electrical connector is mounted to the first bus mount.

4. The DER port jaw assembly of claim 3, further comprising:
a second bus bar mounted to the second bus mount;
a second DER port meter jaw mounted to the second bus mount and electrically coupled to the second bus bar; and
a second DER electrical connector mounted to the second bus mount and electrically coupled to the second bus bar.

5. The DER port jaw assembly of claim 4, wherein the divider is positioned between the DER port meter jaw and the second DER port meter jaw, and wherein the divider is positioned between the DER electrical connector and the second DER electrical connector.

6. A meter jaw block assembly comprising:
an insulating block; and
a DER port jaw assembly mounted to the insulating block, the DER port jaw assembly comprising:
a base;
a bus bar mounted to the base;
a DER port meter jaw mounted to the base and electrically coupled to the bus bar; and
a DER electrical connector mounted to the base and electrically coupled to the bus bar.

7. The meter jaw block assembly of claim 6, wherein the base comprises a divider and first and second bus mounts extending laterally outward from the divider.

8. The meter jaw block assembly of claim 7, wherein each of the bus bar, the DER port meter jaw, and the DER electrical connector is mounted to the first bus mount.

9. The meter jaw block assembly of claim 8, further comprising:
a second bus bar mounted to the second bus mount;
a second DER port meter jaw mounted to the second bus mount and electrically coupled to the second bus bar; and
a second DER electrical connector mounted to the second bus mount and electrically coupled to the second bus bar.

10. The meter jaw block assembly of claim 9, wherein the divider is positioned between the DER port meter jaw and the second DER port meter jaw, and wherein the divider is positioned between the DER electrical connector and the second DER electrical connector.

11. A meter socket comprising:
a meter socket enclosure;
an insulating block; and
a DER port jaw assembly mounted to the insulating block, the DER port jaw assembly comprising:
a base;
a bus bar mounted to the base;
a DER port meter jaw mounted to the base and electrically coupled to the bus bar; and
a DER electrical connector mounted to the base and electrically coupled to the bus bar.

12. The meter socket of claim 11, wherein the base comprises a divider and first and second bus mounts extending laterally outward from the divider.

13. The meter socket of claim 12, wherein each of the bus bar, the DER port meter jaw, and the DER electrical connector is mounted to the first bus mount.

14. The meter socket of claim 13, further comprising:
a second bus bar mounted to the second bus mount;
a second DER port meter jaw mounted to the second bus mount and electrically coupled to the second bus bar; and
a second DER electrical connector mounted to the second bus mount and electrically coupled to the second bus bar.

15. The meter socket of claim 14, wherein the divider is positioned between the DER port meter jaw and the second DER port meter jaw, and wherein the divider is positioned between the DER electrical connector and the second DER electrical connector.
